(19) United States
(12) Patent Application Publication
(10) Pub. No.: US 2025/0133703 A1
(43) Pub. Date: Apr. 24, 2025

(54) RADIATOR INSTALLATION COMPONENT, RADIATOR ASSEMBLY, SHIELDING SHELL ASSEMBLY AND CONNECTOR

(71) Applicant: Tyco Electronics (Shanghai) Co., Ltd., Shanghai (CN)

(72) Inventors: Jin (Ralf) Zhang, Shanghai (CN); Jiwang (Arthur) Jin, Shanghai (CN); Xingjie (Steven) Ge, Shanghai (CN); Guangming (Suny) Zhao, Shanghai (CN)

(73) Assignee: Tyco Electronics (Shanghai) Co., Ltd., Shanghai (CN)

(21) Appl. No.: 18/924,461

(22) Filed: Oct. 23, 2024

(30) Foreign Application Priority Data
Oct. 23, 2023 (CN) 202311377635.9

(51) Int. Cl. H05K 7/20; H01R 13/6582

(52) U.S. Cl. CPC H05K 7/20418; H01R 13/6582

(57) ABSTRACT

A radiator installation component includes a bottom plate defining a bottom opening, a top plate forming an elastic pressing member, a front end plate connected between front ends of the bottom plate and the top plate, and an inner cavity for inserting a radiator defined between the bottom plate, the top plate, and the front end plate. The radiator installation component is installed in a shielding shell of a connector and divides an internal space of the shielding shell into upper and lower accommodating chambers. The bottom opening formed in the bottom plate allows a bottom protrusion of the radiator to protrude into the lower accommodating chamber of the shielding shell. The elastic pressing member is adapted to press on a top surface of the radiator, so that the bottom protrusion of the radiator is in thermal contact with a mating connector inserted into the lower accommodating chamber.

### CROSS-REFERENCE TO RELATED APPLICATION

This application claims the benefit of Chinese Patent Application No. CN202311377635.9 filed on Oct. 23, 2023 in the State Intellectual Property Office of China, the whole disclosure of which is incorporated herein by reference.

### FIELD OF THE DISCLOSURE

The present disclosure relates to a radiator installation component, a radiator assembly comprising the radiator installation component, a shielding shell assembly comprising the radiator assembly, and a connector comprising the shielding shell assembly.

### BACKGROUND OF THE INVENTION

For a high-power connector, a radiator is required. In the prior art, a high-power connector typically includes a shielding shell, a radiator, a radiator installation component, and an elastic pressing component. The radiator installation component is installed in the shielding shell to separate the internal space of the shielding shell into upper and lower accommodating chambers. The radiator is installed in the inner cavity of the radiator installation component, and the elastic pressing component is assembled on the radiator installation component to apply a predetermined pressing pressure on the top of the radiator. This ensures reliable thermal contact between the radiator and the mating connector inserted into the lower accommodating chamber, thereby improving the heat dissipation performance of the connector. However, in the prior art, due to the fact that the radiator installation component and the elastic pressing component are two separate independent components, they need to be manufactured separately using two sets of molds and assembled together. This leads to more complex assembly of the connector, lower production efficiency, and higher costs.

### SUMMARY OF THE INVENTION

According to an embodiment of the present disclosure, a radiator installation component includes a bottom plate defining a bottom opening, a top plate forming an elastic pressing member, a front end plate connected between front ends of the bottom plate and the top plate, and an inner cavity for inserting a radiator defined between the bottom plate, the top plate, and the front end plate. The radiator installation component is installed in a shielding shell of a connector and divides an internal space of the shielding shell into upper and lower accommodating chambers. The bottom opening formed in the bottom plate allows a bottom protrusion of the radiator to protrude into the lower accommodating chamber of the shielding shell. The elastic pressing member is adapted to press on a top surface of the radiator, so that the bottom protrusion of the radiator is in thermal contact with a mating connector inserted into the lower accommodating chamber.

### BRIEF DESCRIPTION OF THE DRAWINGS

The accompanying drawings incorporated therein and forming a part of the specification illustrate the present disclosure and, and together with the description, further serve to explain the principles of the disclosure and to enable those skilled in the relevant art to manufacture and use the embodiments described herein.

FIG. 1 shows an illustrative perspective view of a shielding shell assembly of a connector according to an exemplary embodiment of the present invention;

FIG. 2 shows an illustrative exploded view of the shielding shell assembly of a connector according to an exemplary embodiment of the present invention;

FIG. 3 shows a cross-sectional view of a shielding shell assembly of a connector according to an exemplary embodiment of the present invention;

FIG. 4 shows an illustrative perspective view of a radiator assembly of a connector according to an exemplary embodiment of the present invention when viewed from the top;

FIG. 5 shows an illustrative perspective view of a radiator assembly of a connector according to an exemplary embodiment of the present invention when viewed from the bottom;

FIG. 6 shows an illustrative exploded view of the radiator assembly of a connector according to an exemplary embodiment of the present invention when viewed from the top;

FIG. 7 shows an illustrative exploded view of the radiator assembly of a connector according to an exemplary embodiment of the present invention when viewed from the bottom;

FIG. 8 shows a cross-sectional view of a radiator assembly of a connector according to an exemplary embodiment of the present invention; and

FIG. 9 shows an exploded sectional view of a radiator assembly of a connector according to an exemplary embodiment of the present invention.

The features disclosed in this disclosure will become more apparent in the following detailed description in conjunction with the accompanying drawings, where similar reference numerals always identify the corresponding components. In the accompanying drawings, similar reference numerals typically represent identical, functionally similar, and/or structurally similar components. Unless otherwise stated, the drawings provided throughout the entire disclosure should not be construed as drawings drawn to scale.

### DETAILED DESCRIPTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

According to an embodiment of the present disclosure, a radiator installation component is provided. The radiator installation component is an integral piece, and is adapted to be installed in a shielding shell of a connector, and to divide an internal space of the shielding shell into a lower accommodating chamber and an upper accommodating chamber. The radiator installation component comprises a bottom plate, a top plate, and a front end plate. The front end plate is connected between the front ends of the bottom plate and the top plate, and an inner cavity for inserting a radiator is defined between the bottom plate, the top plate, and the front end plate. A bottom opening is formed in the bottom plate to allow a bottom protrusion of the radiator to protrude into the lower accommodating chamber of the shielding shell through the bottom opening. An elastic pressing member is formed on the top plate, which is used to press on the top surface of the radiator, so that the bottom protrusion of the radiator can be in thermal contact with a mating connector inserted into the lower accommodating chamber.

According to another general concept of the present invention, there is provided a radiator assembly. The radiator assembly comprises of: the above radiator installation component; and a radiator which is installed in the inner cavity of the radiator installation component.

According to another embodiment of the present invention, a shielding shell assembly is provided. The shielding shell assembly comprises a shielding shell, and the above radiator assembly installed in the shielding shell.

According to another embodiment of the present invention, a connector is provided. The connector comprises the above shielding shell assembly, a terminal holder installed in the shielding shell, and a terminal fixed in the terminal holder. The terminal is used for mating with a mating terminal of a mating connector inserted into the shielding shell.

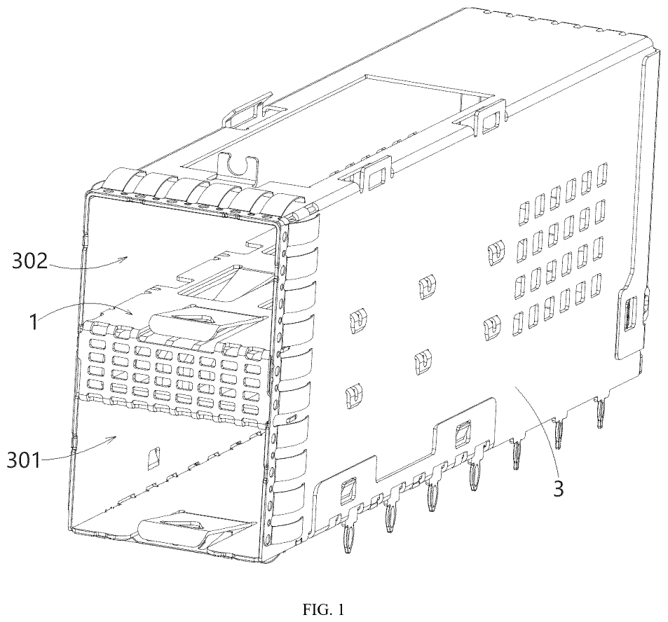

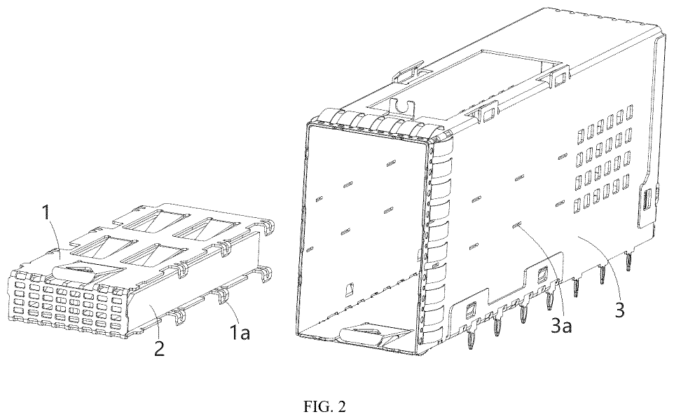

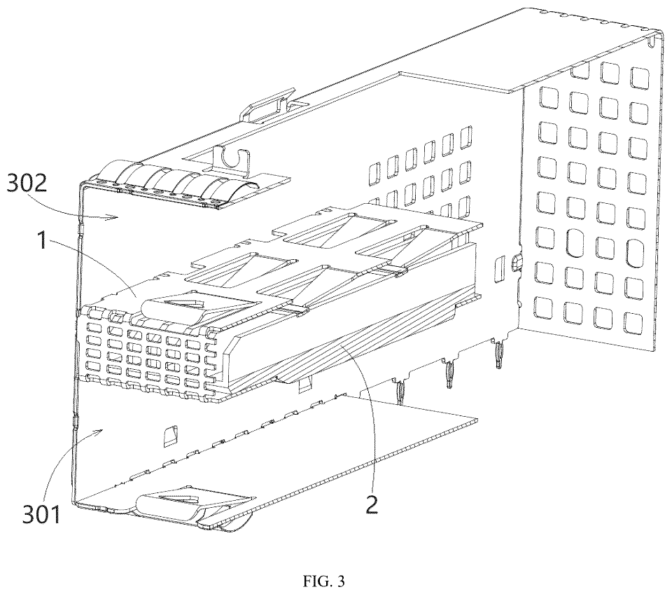

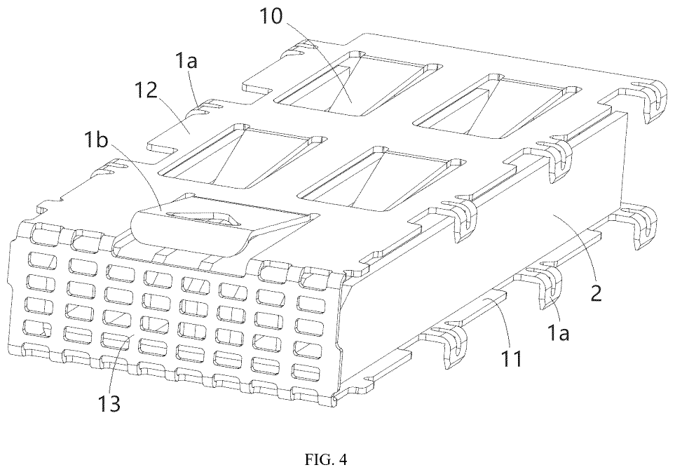

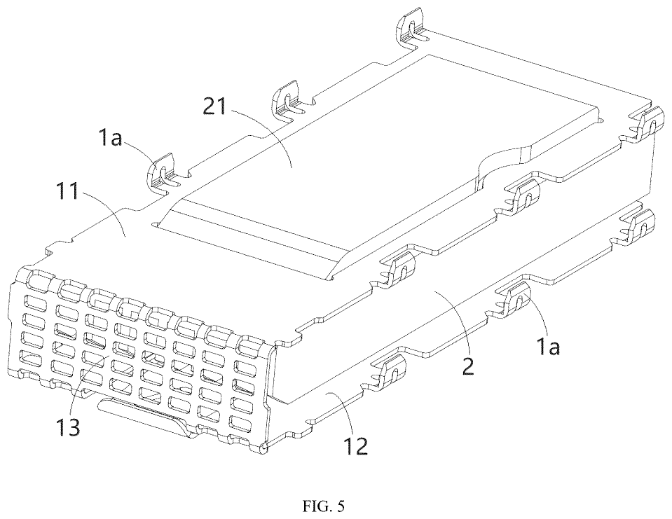

FIG. 1 shows an illustrative perspective view of a shielding shell assembly of a connector according to an exemplary embodiment of the present invention. FIG. 2 shows an illustrative exploded view of the shielding shell assembly of a connector according to an exemplary embodiment of the present invention. FIG. 3 shows a cross-sectional view of a shielding shell assembly of a connector according to an exemplary embodiment of the present invention. FIG. 4 shows an illustrative perspective view of a radiator assembly of a connector according to an exemplary embodiment of the present invention when viewed from the top. FIG. 5 shows an illustrative perspective view of the radiator assembly of a connector according to an exemplary embodiment of the present invention when viewed from the bottom.

As shown in FIGS. 1-5, in an exemplary embodiment of the present invention, a radiator installation component 1 is disclosed. The radiator installation component 1 is an integral part. The radiator installation component 1 is used to be installed in a shielding shell 3 of a connector, to divide the internal space of the shielding shell 3 into a lower accommodating chamber 301 and an upper accommodating chamber 302.

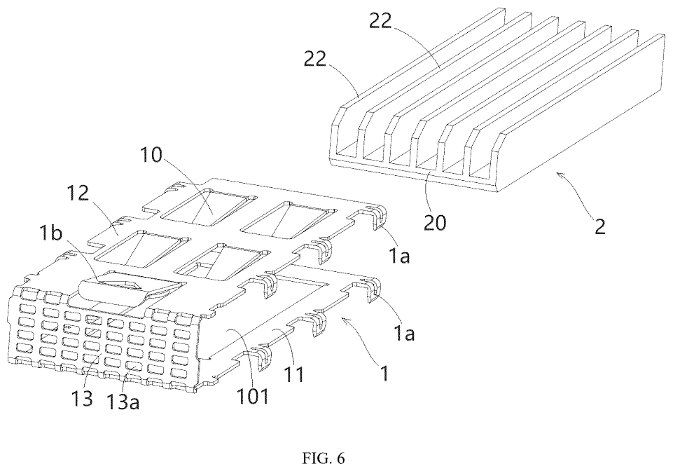

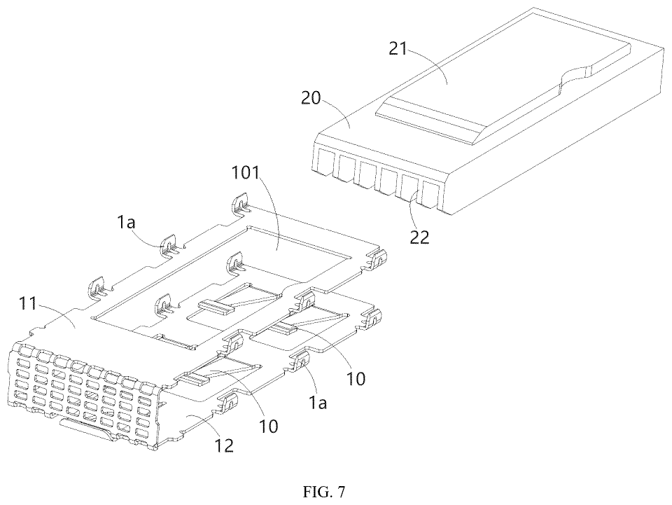

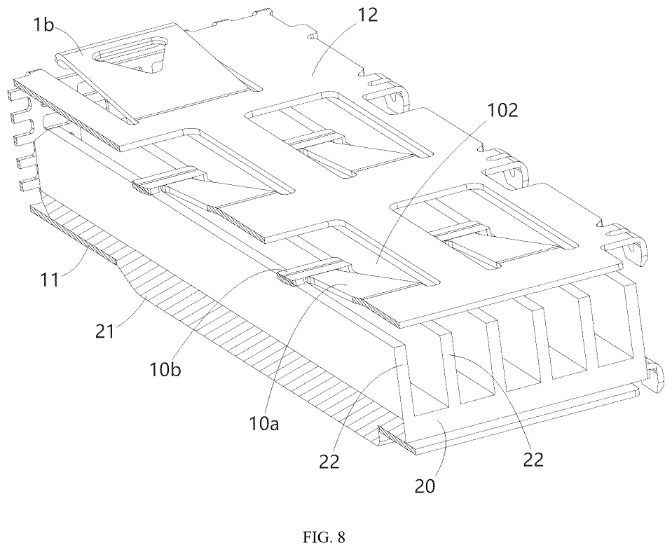

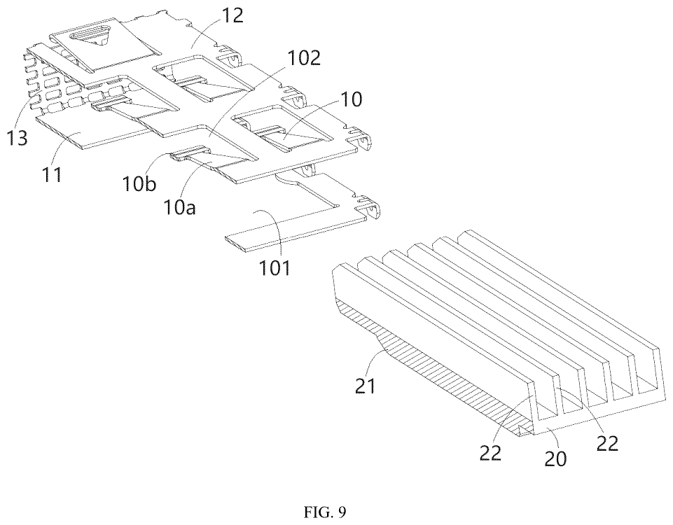

FIG. 6 shows an illustrative exploded view of the radiator assembly of a connector according to an exemplary embodiment of the present invention when viewed from the top. FIG. 7 shows an illustrative exploded view of the radiator assembly of a connector according to an exemplary embodiment of the present invention when viewed from the bottom. FIG. 8 shows a cross-sectional view of a radiator assembly of a connector according to an exemplary embodiment of the present invention. FIG. 9 shows an exploded sectional view of a radiator assembly of a connector according to an exemplary embodiment of the present invention.

As shown in FIGS. 1-9, in the illustrated embodiments, the radiator installation component 1 includes a bottom plate 11, a top plate 12, and a front end plate 13. The front end plate 13 is connected between the front ends of the bottom plate 11 and the top plate 12, an inner cavity for inserting the radiator 2 is defined between the bottom plate 11, the top plate 12, and the front end plate 13. A bottom opening 101 is formed in the bottom plate 11 to allow the bottom protrusion 21 of the radiator 2 to protrude into the lower accommodating chamber 301 of the shielding shell 3 through the bottom opening 101. An elastic pressing member 10 is formed on the top plate 12, which is used to press on the top surface of radiator 2 to ensure reliable thermal contact between the bottom protrusion 21 of radiator 2 and a mating connector (not shown) inserted into the lower accommodating chamber 301. In an exemplary embodiment of the present invention, the radiator installation component 1 may be an integral stamped part or an integral machined part.

The elastic pressing member 10 comprises a cantilever part 10a and a pressing part 10b. The cantilever part 10a is connected to the top plate 12 and extends obliquely from the top plate 12 into the inner cavity of the radiator installation component 1. The pressing part 10b is connected to the end of the cantilever part 10a and is used to press on the top surface of the heat dissipation fins 22 of the radiator 2.

The root of the cantilever part 10a is connected to the top plate 12 and extends a predetermined length by tilting forward and downward from its root. The pressing part 10b extends in a direction perpendicular to the cantilever part 10a, so that the elastic pressing member 10 forms a T-shape. The pressing part 10b is suitable for simultaneously pressing on the top surface of multiple heat dissipation fins 22 of radiator 2.

In the illustrated embodiments, multiple elastic pressing members 10 are formed on the top plate 12, and the multiple elastic pressing members 10 are arranged in an array. Multiple windows 102 are formed in the top plate 12, and multiple elastic pressing members 10 are respectively suspended in the multiple windows 102.

The radiator installation component 1 has a rear port opposite to its front end plate 13 to allow the radiator 2 to be inserted into the inner cavity of the radiator installation component 1 through the rear port.

The front end plate 13 of the radiator installation component 1 is suitable to rest against the front end face of the radiator 2, and ventilation holes 13a arranged in a honeycomb pattern are formed in the front end plate 13 of the radiator installation component 1 to communicate the inner cavity of the radiator installation component 1 with the external gas.

Multiple connecting pieces 1a are formed on the lateral sides of the bottom plate 11 and top plate 12 of the radiator installation component 1, respectively. The connecting pieces 1a are suitable for passing through the slits 3a in the shielding shell 3 and being bent 90 degrees to fix the radiator installation component 1 to the shielding shell 3.

An elastic buckle 1b is also formed on the top plate 12 of the radiator installation component 1. The elastic buckle 1b is close to the front end plate 13 and is used to engage with the mating connector inserted into the upper accommodating chamber 302 to lock the mating connector in the upper accommodating chamber 302.

In another exemplary embodiment of the present invention, a radiator assembly is also disclosed. The radiator assembly includes: the radiator installation component 1 and a radiator 2. The radiator 2 is installed in the inner cavity of radiator installation component 1. The radiator 2 comprises a base plate 20, a bottom protrusion 21, and heat dissipation fins 22. The bottom protrusion 21 is formed on the bottom surface of the base plate 20. The heat dissipation fins 22 are formed on the top surface of the base plate 20. The bottom protrusion 21 of radiator 2 is suitable for protruding into the lower accommodating chamber 301 of the shielding shell 3 of the connector through the bottom opening 101 in the bottom plate 11 of radiator installation component 1. The elastic pressing member 10 on the top plate 12 of radiator installation component 1 is pressed onto the top surface of the heat dissipation fins 22 of radiator 2 to ensure reliable thermal contact between the bottom protrusion 21 of radiator 2 and the mating connector inserted into the lower accommodating chamber 301.

In another exemplary embodiment of the present invention, a shielding shell assembly is also disclosed. The shielding shell assembly includes a shielding shell 3 and the radiator assembly. The radiator assembly is installed in the shielding shell 3. The radiator installation component 1 divides the internal space of the shielding shell 3 into a lower accommodating chamber 301 and an upper accommodating chamber 302. The bottom protrusion 21 of the radiator 2 protrudes into the lower accommodating chamber 301 of the shielding shell 3 through the bottom opening 101 in the bottom plate 11 of the radiator installation component 1, in order to make thermal contact with the mating connector inserted into the lower accommodating chamber 301.

Multiple slits 3a are formed in the two side walls of the shielding shell 3, and the connecting pieces 1a on the bottom plate 11 and top plate 12 of the radiator installation component 1 pass through the slits 3a of the shielding shell 3 and are bent 90 degrees, so that the radiator installation component 1 is fixed to the shielding shell 3. In an exemplary embodiment of the present invention, the shielding shell 3 may be an integral stamped part.

In another exemplary embodiment of the present invention, a connector is also disclosed. The connector includes: the shielding shell assembly, a terminal holder, and a terminal. The terminal holder is installed in the shielding shell 3. The terminal is fixed to the terminal holder. The terminal is used to mate with a mating terminal of the mating connector inserted into the shielding shell 3.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A radiator installation component, comprising:
a bottom plate defining a bottom opening;
a top plate forming an elastic pressing member;
a front end plate connected between front ends of the bottom plate and the top plate;
an inner cavity for inserting a radiator is defined between the bottom plate, the top plate, and the front end plate, wherein:
the radiator installation component is adapted to be installed in a shielding shell of a connector, and to divide an internal space of the shielding shell into a lower accommodating chamber and an upper accommodating chamber;
the bottom opening formed in the bottom plate is adapted to allow a bottom protrusion of the radiator to protrude into the lower accommodating chamber of the shielding shell; and
the elastic pressing member is adapted to press on a top surface of the radiator and place the bottom protrusion of the radiator in thermal contact with a mating connector inserted into the lower accommodating chamber.

2. The radiator installation component according to claim 1, wherein the radiator installation component is an integral stamped component or an integral machined component.

3. The radiator installation component according to claim 1, wherein the elastic pressing member includes:
a cantilever part connected to the top plate and extending obliquely from the top plate into the inner cavity of the radiator installation component; and
a pressing part connected to the end of the cantilever part and adapted to press on the top surface of the heat dissipation fins of the radiator.

4. The radiator installation component according to claim 3, wherein the root of the cantilever part is connected to the top plate and extends a predetermined length by tilting forward and downward from its root.

5. The radiator installation component according to claim 4, wherein:
the pressing part extends in a direction perpendicular to the cantilever part; and
the pressing part is adapted to simultaneously press on a top surface of multiple heat dissipation fins of the radiator.

6. The radiator installation component according to claim 5, wherein multiple elastic pressing members are formed on the top plate and are arranged in an array.

7. The radiator installation component according to claim 6, wherein multiple windows are formed in the top plate, and the multiple elastic pressing members are respectively suspended in the multiple windows.

8. The radiator installation component according to claim 1, wherein the radiator installation component has a rear port opposite to its front end plate to allow the radiator to be inserted into the inner cavity of the radiator installation component through the rear port.

9. The radiator installation component according to claim 8, wherein the front end plate of the radiator installation component is adapted to press against the front end face of the radiator, and ventilation holes arranged in a honeycomb pattern are formed in the front end plate of the radiator installation component to communicate the inner cavity of the radiator installation component with the external gas.

10. The radiator installation component according to claim 1, wherein multiple connecting pieces are formed on lateral sides of the bottom plate and top plate of the radiator installation component, respectively, the connecting pieces are suitable for passing through the slits in the shielding shell and being bent 90 degrees to fix the radiator installation component to the shielding shell.

11. The radiator installation component according to claim 1, wherein an elastic buckle is formed on the top plate of the radiator installation component proximate to the front end plate for engaging with the mating connector inserted into the upper accommodating chamber to lock the mating connector in the upper accommodating chamber.

12. A radiator assembly, comprising:
a radiator;
a radiator installation component, including:
a bottom plate defining a bottom opening;
a top plate forming an elastic pressing member;
a front end plate connected between front ends of the bottom plate and the top plate;
an inner cavity in which the radiator is inserted is defined between the bottom plate, the top plate, and the front end plate, wherein:
the radiator installation component is adapted to be installed in a shielding shell of a connector, and to divide an internal space of the shielding shell into a lower accommodating chamber and an upper accommodating chamber;
the bottom opening formed in the bottom plate is adapted to allow a bottom protrusion of the radiator to protrude into the lower accommodating chamber of the shielding shell; and
the elastic pressing member presses on a top surface of the radiator and is adapted to place the bottom protrusion of the radiator in thermal contact with a mating connector inserted into the lower accommodating chamber.

13. The radiator assembly according to claim 10, wherein the radiator comprises:
a base plate;
a bottom protrusion s formed on a bottom surface of the base plate; and
heat dissipation fins formed on a top surface of the base plate.

14. The radiator assembly according to claim 13, wherein:
the bottom protrusion of the radiator protrudes into the lower accommodating chamber of the shielding shell of the connector through the bottom opening in the bottom plate of the radiator installation component; and
the elastic pressing member on the top plate of the radiator installation component is pressed onto the top surface of the heat dissipation fins of the radiator.

15. A shielding shell assembly, comprising:
a shielding shell; and
the radiator assembly as claimed in claim 14 installed in the shielding shell.

16. The shielding shell assembly according to claim 15, wherein the radiator installation component divides the internal space of the shielding shell into a lower accommodating chamber and an upper accommodating chamber.

17. The shielding shell assembly according to claim 16, wherein the bottom protrusion of the radiator protrudes into the lower accommodating chamber of the shielding shell through the bottom opening in the bottom plate of the radiator installation component to make thermal contact with a mating connector inserted into the lower accommodating chamber.

18. The shielding shell assembly according to claim 17, wherein multiple slits are formed in the two side walls of the shielding shell.

19. The shielding shell assembly according to claim 18, wherein the connecting pieces on the bottom plate and top plate of the radiator installation component pass through the slits of the shielding shell and are bent 90 degrees, such that the radiator installation component is fixed to the shielding shell.

20. The shielding shell assembly according to claim 15, wherein the shielding shell is an integral stamped piece.
